(19) United States
(12) Patent Application Publication
(10) Pub. No.: US 2025/0324143 A1
(43) Pub. Date: Oct. 16, 2025

(54) OBJECT CONNECTION METHOD, ELECTRONIC DEVICE, AND STORAGE MEDIUM

(71) Applicant: Lemon Inc., Grand Cayman (KY)

(72) Inventors: Clarence WANG, Culver City, CA (US); Runze Zhang, Los Angeles, CA (US)

(21) Appl. No.: 18/988,733

(22) Filed: Dec. 19, 2024

(30) Foreign Application Priority Data
Apr. 12, 2024 (CN) 202410444787.4

(51) Int. Cl. H04N 21/81; H04N 21/431

(52) U.S. Cl. CPC H04N 21/8153; H04N 21/4312

(57) ABSTRACT

Embodiments of the present disclosure provide an object connection method and apparatus, an electronic device, a storage medium, and a program product. The object connection method includes: in response to a first trigger operation, acquiring a first action position and a second action position based on the first trigger operation, where the first action position is used to determine a first object to be connected; determining a second object capable of establishing a connection to the first object, and creating a detection element corresponding to the second object, where the second object is in a detection region of the detection element, and an area of the detection region is greater than an area of the second object; and in response to the second action position being in the detection region, connecting the first object to the second object in the detection region in response to a second trigger operation.

### CROSS-REFERENCE TO RELATED APPLICATION

The present application claims the priority to Chinese Patent Application No. 202410444787.4, filed on Apr. 12, 2024, the entire disclosure of which is incorporated herein by reference as portion of the present application.

### TECHNICAL FIELD

Embodiments of the present disclosure relate to an object connection method and apparatus, an electronic device, a storage medium, and a program product.

### BACKGROUND

In a graphic editing scenario, a plurality of graphs often need to be connected to each other. In the related art, a user needs to drag a connection line to a specified point in a graph and then release a mouse button to complete connection.

However, during the process of object connection, a plurality of objects may be scaled to very small sizes to be located in an editing window, where performing the object connection based on the method described above imposes a high requirement on operational precision, which may cause a case in which a target object to be connected cannot be precisely located and thus affects accuracy and efficiency of graph connection.

### SUMMARY

The present disclosure provides an object connection method and apparatus, an electronic device, a storage medium, and a program product.

The embodiments of the present disclosure provide an object connection method, and the method includes:
in response to a first trigger operation, acquiring a first action position and a second action position based on the first trigger operation, where the first action position is used to determine a first object to be connected;
determining a second object capable of establishing a connection to the first object, and creating a detection element corresponding to the second object, where the second object is in a detection region of the detection element, and an area of the detection region is greater than an area of the second object; and
in response to the second action position being in the detection region, connecting the first object to the second object in the detection region in response to a second trigger operation.

The embodiments of the present disclosure further provide an object connection apparatus, and the apparatus includes:
a trigger module configured to, in response to a first trigger operation, acquire a first action position and a second action position based on the first trigger operation, where the first action position is used to determine a first object to be connected;
a detection module configured to determine a second object capable of establishing a connection to the first object, and create a detection element corresponding to the second object, where the second object is in a detection region of the detection element, and an area of the detection region is greater than an area of the second object; and
a connection module configured to, in response to the second action position being in the detection region, connect the first object to the second object in the detection region in response to a second trigger operation.

The embodiments of the present disclosure further provide an electronic device, and the electronic device includes:
one or more processors; and
a storage apparatus configured to store one or more programs, where
the one or more programs, when executed by the one or more processors, cause the one or more processors to implement the object connection method according to any one of the embodiments of the present disclosure.

The embodiments of the present disclosure further provide a storage medium including computer-executable instructions, where the computer-executable instructions, when executed by a computer processor, are used to implement the object connection method according to any one of the embodiments of the present disclosure.

The embodiments of the present disclosure further provide a computer program product, where the computer program product includes a computer program that, when executed by a processor, causes the object connection method according to any one of the embodiments of the present disclosure to be implemented.

### BRIEF DESCRIPTION OF DRAWINGS

The foregoing and other features, advantages, and aspects of embodiments of the present disclosure become more apparent with reference to the following specific implementations and in conjunction with the drawings. Throughout the drawings, the same or similar reference numerals denote the same or similar elements. It should be understood that the drawings are schematic and that parts and elements are not necessarily drawn to scale.

FIG. 1 is a schematic flowchart of an object connection method according to an embodiment of the present disclosure;

FIG. 2 is a schematic diagram of an effect of a detection region according to an embodiment of the present disclosure;

FIG. 3 is a schematic flowchart of another object connection method according to an embodiment of the present disclosure;

FIG. 4 is a schematic flowchart of an object connection method according to an embodiment of the present disclosure;

FIG. 5 is a schematic diagram of a structure of an object connection apparatus according to an embodiment of the present disclosure; and

FIG. 6 is a schematic diagram of a structure of an electronic device according to an embodiment of the present disclosure.

### DETAILED DESCRIPTION

The embodiments of the present disclosure are described in more detail below with reference to the drawings. Although some embodiments of the present disclosure are shown in the drawings, it should be understood that the present disclosure may be implemented in various forms and should not be construed as being limited to the embodiments set forth herein. Rather, these embodiments are provided for a more thorough and complete understanding of the present disclosure. It should be understood that the drawings and the embodiments of the present disclosure are only for exemplary purposes, and are not intended to limit the scope of protection of the present disclosure.

It should be understood that the various steps described in the method implementations of the present disclosure may be performed in different orders, and/or performed in parallel. Furthermore, additional steps may be included and/or the execution of the illustrated steps may be omitted in the method implementations. The scope of the present disclosure is not limited in this respect.

The term “include” used herein and the variations thereof are an open-ended inclusion, namely, “include but not limited to”. The term “based on” is “at least partially based on”. The term “an embodiment” means “at least one embodiment”. The term “another embodiment” means “at least one another embodiment”. The term “some embodiments” means “at least some embodiments”. Related definitions of the other terms will be given in the description below.

It should be noted that concepts such as “first” and “second” mentioned in the present disclosure are only used to distinguish different apparatuses, modules, or units, and are not used to limit the sequence of functions performed by these apparatuses, modules, or units or interdependence.

It should be noted that the modifiers “one” and “a plurality of” mentioned in the present disclosure are illustrative and not restrictive, and those skilled in the art should understand that unless the context clearly indicates otherwise, the modifiers should be understood as “one or more”.

The names of messages or information exchanged between a plurality of apparatuses in the implementations of the present disclosure are used for illustrative purposes only, and are not used to limit the scope of these messages or information.

It can be understood that before the use of the technical solutions disclosed in the embodiments of the present disclosure, the user shall be informed of the type, range of use, use scenarios, etc., of personal information involved in the present disclosure in an appropriate manner in accordance with the relevant laws and regulations, and the authorization of the user shall be obtained.

For example, in response to reception of an active request from the user, prompt information is sent to the user to clearly inform the user that a requested operation will require access to and use of the personal information of the user. As such, the user can independently choose, based on the prompt information, whether to provide the personal information to software or hardware, such as an electronic device, an application, a server, or a storage medium, that performs operations in the technical solutions of the present disclosure.

As an optional but non-limiting implementation, in response to the reception of the active request from the user, the prompt information may be sent to the user in the form of, for example, a pop-up window, in which the prompt information may be presented in text. Furthermore, the pop-up window may further include a selection control for the user to choose whether to “agree” or “disagree” to provide the personal information to the electronic device.

It can be understood that the above process of notifying and acquiring the authorization of the user is only illustrative and does not constitute a limitation on the implementations of the present disclosure, and other manners that satisfy the relevant laws and regulations may also be applied in the implementations of the present disclosure.

It can be understood that the data involved in the technical solutions (including, but not limited to, the data itself and the access to or use of the data) shall comply with the requirements of corresponding laws, regulations, and relevant provisions.

Before the technical solutions are described, an exemplary description of an application scenario may be given. The technical solutions can be applied to any scenario of object connection. In order to describe the technical solutions more clearly, the process of implementing the technical solutions can be illustrated with an example of a graphic editing scenario. For example, in the graphic editing scenario, any two port identifiers may be connected by means of click and drag. In response to a click-and-drag trigger operation on any port identifier being detected, a drag trajectory can be generated based on a drag operation. A port identifier cannot be connected to a target port until a drag release operation is input on the preset identifier dragged to the target port, and no connection prompt is displayed in an editing window before the drag release operation is input. As such, during the process of connection, in response to a plurality of objects being scaled to very small sizes to be in the editing window, a target object to be connected may not be precisely located during the object connection performed based on the method described above, thereby causing the problem of reducing object connection accuracy and connection efficiency.

In this case, based on the technical solutions of the embodiments of the present disclosure, in response to a click-and-drag trigger operation input for any port of the editing window being detected, a click position may be used as a first action position, and then a port identifier to be connected may be determined based on the first action position, which is used as a first port. Further, a drag trigger operation may be continued, and a second action position may be acquired during the process of performing the drag trigger operation. In addition, during the process of performing the drag operation, a second port capable of establishing a connection to the first port is determined, and a detection element corresponding to the second port is created. Further, in response to a drag release operation being detected, a last second action position obtained may be determined based on the drag release operation, and whether the second action position is in a detection region of the detection element may be determined. In response to the second action position being in the detection region, the first port may be connected to the second port in the detection region. Therefore, the beneficial effects of reducing operational difficulty in object connection, improving operational experience of users, and increasing the accuracy and efficiency of object connection are achieved.

FIG. 1 is a schematic flowchart of an object connection method according to the embodiments of the present disclosure. The embodiments of the present disclosure are applicable to the case of deleting an object and then restoring the object after deletion, and the method may be performed by an object connection apparatus. The apparatus may be implemented in the form of software and/or hardware. Optionally, the apparatus may be implemented by an electronic device, and the electronic device may be a mobile terminal, a PC, a server, or the like.

As shown in FIG. 1, the method in the present embodiment may include the following steps.

S110: in response to a first trigger operation, acquiring a first action position and a second action position based on the first trigger operation, where the first action position is used to determine a first object to be connected.

The first trigger operation may be understood as a trigger operation causing an object to be connected to be in a connection state. Optionally, the first trigger operation may include a click-and-drag trigger operation, a click trigger operation for a connection control and the object to be connected, a selection trigger operation for the object to be connected (for example, a click trigger operation for the object to be connected that is input based on a right mouse button, a click trigger operation for the object to be connected that is input based on a left mouse button in response to a click and hold operation is input for an object selection control, or the like), a parameter editing trigger operation, and the like.

The first action position may be understood as a position representing a connection starting point in a single connection process. The first action position is used to determine the first object to be connected. The first object may be understood as an object located at the connection starting point in a single connection process. The first object may include any object on which a connection operation can be performed. Optionally, the first object may be a port identifier in one or more graphic elements in a graphic editing tool.

In the embodiments of the present disclosure, different first trigger operations may correspond to various methods of determining the first action position. Optionally, in response to the first trigger operation being the click-and-drag trigger operation, a position of a click performed by an input device can be used as the first action position. Further, a drag operation can be performed starting from the first action position. Alternatively, in response to the first trigger operation being the selection trigger operation for the object to be connected, a position of the first click performed by an input device (such as a mouse) in a single connection process can be used as the first action position. Alternatively, in response to the first trigger operation being the parameter editing trigger operation, the first action position may be determined based on parameter information (such as coordinate information or an object identifier) input in an editing item of the connection starting point.

The second action position may be understood as an action position other than the first action position that is acquired during the process of performing the first trigger operation. There may be one or more second action positions. It should be noted that different first trigger operations may correspond to various second action positions. Optionally, in response to the first trigger operation being the click-and-drag trigger operation, the second action position may include a position representing the end of the connection state in a single connection process and/or a position in the middle of a connection mark in a single connection process, i.e., an action position other than the first action position that is acquired during the process of performing drag operation. For example, the connection mark may include a connection trajectory, etc. Alternatively, in response to the first trigger operation being the selection trigger operation for the object to be connected, the second action position may be a position representing the end of the connection state in a single connection process, and a position of the last click performed by an input device in the single connection process may be used as the second action position. Alternatively, in response to the first trigger operation being the parameter editing trigger operation, the second action position may be a position representing the end of the connection state in a single connection process, and the second action position may be determined based on parameter information (such as coordinate information or an object identifier) input in an editing item of the connection end point.

In the embodiments of the present disclosure, in response to the first trigger operation being detected, the first action position and the second action position may be determined and acquired based the first trigger operation.

For example, assuming that the first trigger operation is the click-and-drag trigger operation, in response to a click trigger operation for any position performed by the mouse being detected and the mouse button being not released to continue a drag operation, a connection trajectory starting from the position of the click may be generated. In this case, the position of the click may be used as the first action position, and another position on the connection trajectory other than the first action position may be used as the second action position.

S120: determining a second object capable of establishing a connection to the first object, and creating a detection element corresponding to the second object, where the second object is in a detection region of the detection element, and the area of the detection region is greater than the area of the second object.

The second object may be understood as an object capable of establishing a connection relationship with the first object. The second object may include any object on which a connection operation can be performed. Optionally, the second object may be a port identifier of one or more graphic elements in a graphic editing tool. The detection element may be used to detect whether the second action position is in the detection region. In the embodiments of the present disclosure, the detection element may be arranged at a position floating above the second object. An advantage of such configuration is as follows. In response to a preset trigger operation input for the second object being detected, detection for the input preset trigger operation may be performed first based on the detection element. Accordingly, after the detection based on the detection element ends, the preset trigger operation may be caused to act on the second object. In other words, the detection element may be used to intercept the preset trigger operation input for the second object. The detection region may be understood as a region used to detect the second action position to determine whether the first object and the second object can be connected at the second action position. It should be noted that the detection region is in a one-to-one correspondence with the second object. In other words, the detection region may be determined based on the second object. In the embodiments of the present disclosure, the area of the detection region is greater than the area of the second object. An advantage of such configuration is as follows. In the case of exceeding an object border of the second object, detection for the second action position can be performed based on the detection region, thereby extending a range of connection perception for the second object.

It should be noted that in addition to the first object, at least one of the other objects available for connection may be included. The objects available for connection may include an object capable of establishing a connection to the first object, and may also include an object not capable of establishing a connection to the first object.

In the embodiments of the present disclosure, in response to the first action position being acquired, the first object to be connected may be determined based on the first action position. Further, the second object capable of establishing a connection to the first object may be determined based on the first object. It should be noted that the second object may be determined through a variety of methods, which are separately described below.

First method: object types of a plurality of objects are acquired, and a correspondence between the object types is established, to obtain and store type correspondence information. The type correspondence information may include a case where one object type corresponds to one object type, and may further include a case where one object type corresponds to a plurality of object types. Further, the object type of the first object may be acquired in response to the first object being determined, and in response to the object type of the first object being present in the pre-stored type correspondence information, a target object type corresponding to the object type of the first object can be queried based on the type correspondence information. Furthermore, an object of the target object type among the currently included objects available for connection can be used as the second object.

Second method: a plurality of objects may be acquired, and a correspondence between the objects may be established, to obtain and store object correspondence information. The object correspondence information may include a case where one object corresponds to one object, and may further include a case where one object corresponds to a plurality of objects. Further, after the first object is determined, in response to the object correspondence information including the first object, a target object corresponding to the first object can be queried based on the type correspondence information. Furthermore, an object matching the target object among the currently included objects available for connection can be used as the second object.

In the embodiments of the present disclosure, in order to enable a user to more clearly and intuitively understand the second object capable of establishing a connection to the first object, after the second object capable of establishing a connection to the first object is determined, the method further includes: highlighting the second object. Optionally, the highlighting may include setting the second object to a selectable state, zooming in the second object, displaying, in a bold font, object content displayed by the second object, or the like.

In the embodiments of the present disclosure, after the second object is determined, the detection element corresponding to the second object may be created based on the second object. It should be noted that the area of the detection region of the detection element is greater than the area of the second object, so that in response to the second object being determined, the detection element may be created based on an object size parameter of the second object.

Optionally, the creating the detection element corresponding to the second object includes: determining an object border parameter corresponding to the second object, generating, based on the object border parameter, a region border parameter for determining the detection region corresponding to the second object, and creating the detection element corresponding to the second object based on the region border parameter.

The object border parameter may be a parameter representing a size of a minimum border box for the object. It should be noted that both the first object and the second object may have irregular object shapes. In order to make the finally determined detection element more accurate, the minimum border box corresponding to the second object may be created. Further, the object border parameter corresponding to the second object may be determined based on the minimum border box. Optionally, the object border parameter may include a border length, a border height, border vertex coordinates and/or border center coordinates, etc. The region border parameter may be a parameter representing a region size of the detection region. Optionally, the region border parameter may include a border length, a border height, border vertex coordinates and/or border center coordinates, etc.

In the embodiments of the present disclosure, a default border of the second object or a border of a row or column in which the second object is located may be detected to obtain the object border parameter corresponding to the second object. Further, in order to make the area of the detection region of the finally determined detection element greater than the area of the second object, at least some parameters among the object border parameter may be adjusted to expand at least a portion of the default border of the second object or the border of the row or column in which the second object is located, to obtain the region border parameter of the detection region. In short, a border size represented by the region border parameter of the detection region is greater than a size of the default border corresponding to the second object. Further, the region border parameter may be injected into a preset element generation algorithm, to generate the detection element corresponding to the second object based on the region border parameter by means of the preset element generation algorithm. An advantage of such configuration is as follows. The effect of dynamically creating the detection element matching the second object is achieved, which enhances the flexibility of creating the detection element. In response to a plurality of second objects being arranged in a first direction, the default border of the second object or the border of the row or column in which the second object is located may be expanded in a second direction perpendicular to the first direction, to form a region border of the detection region. An advantage of such configuration is as follows. The detection region of the finally created detection element, with the region area greater than the area of the second object, does not overlap with another detection region adjacent thereto and thus does not affect an element detection process of another detection region.

For example, after the object border parameter is obtained, the border length in the object border parameter may be increased by a preset value in a direction away from the second object and close to the first object, while parameter values of other parameters in the object border parameter remain unchanged, to obtain a new object border parameter, where the new object border parameter can be used as the region border parameter.

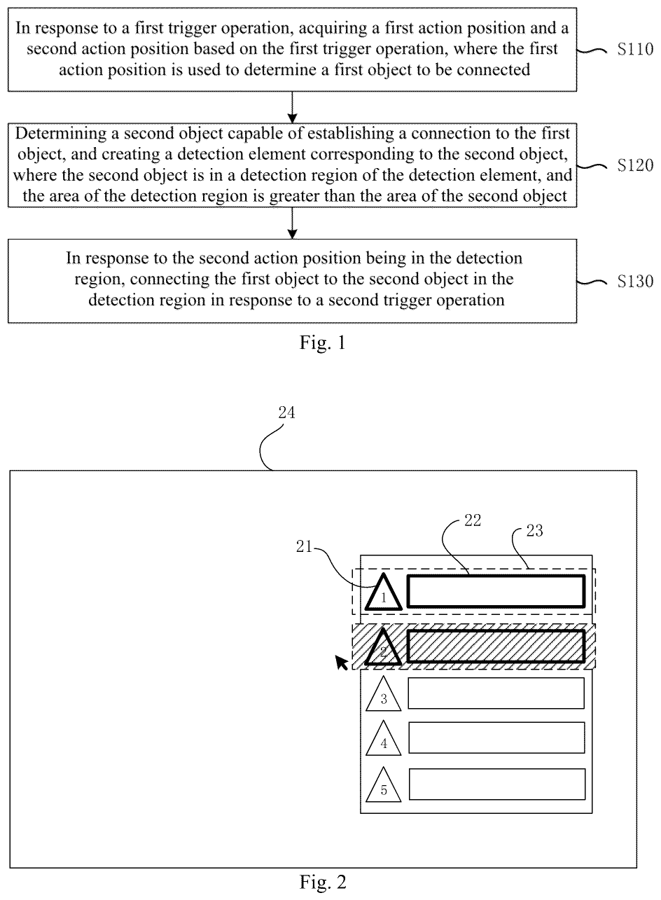

For example, FIG. 2 is a schematic diagram of an effect of a detection region according to an embodiment of the present disclosure. As shown in FIG. 2, five objects may be included, which are an object 1, an object 2, an object 3, an object 4, and an object 5 respectively. The object 1 and the object 2 may be used as second objects capable of establishing a connection to the first object. Moreover, the object 1 and the object 2 may be highlighted. For example, the object 3, the object 4, and the object 5 may be grayed out. For the two second objects, each second object may be represented based on a port identifier 21, and a text identifier of a port corresponding to the second object may be edited based on a block 22. The object 1 and the object 2 are sequentially arranged from top to bottom, and in this case, default borders of the object 1 and the object 2 may be sequentially detected from left to right, to determine object border parameters of the object 1 and the object 2. Further, in order to enable quick location to the corresponding second object from an adjacent region close to the second object, a portion of the default border adjacent to the second object may be expanded to the left, to obtain a detection region 23.

It should be noted that the area of the detection region is greater than the area of the second object, so that the second object can be located inside the detection region.

It should also be noted that the detection element may be created based on a preset framework, and the detection element may be at the same level as a data element represented by the second object. The detection element that is created based on the preset framework and that is at the same level as the data element of the second object may perfectly support interface scaling and dynamic structure adjustment.

In the embodiments of the present disclosure, after the detection element corresponding to the second object is created, the detection for the second action position may be performed based on the detection element, to determine whether the second action position is in the detection region. Moreover, in order to enable the user to more clearly and intuitively observe the detection region and thus intuitively determine the position of the second object to be connected to the first object, after the detection element corresponding to the second object is created, the object connection method further includes: highlighting the detection region in response to the distance between the second action position and the detection region being less than or equal to a preset distance.

The preset distance may be used to indicate whether to highlight the detection region. The preset distance may be any value. Optionally, the highlighting may include highlighting the detection region, zooming in the detection region, setting a display color of the detection region to a color different from a display color of another region, or the like.

In the embodiments of the present disclosure, after the detection element corresponding to the second object is created, the distance between the second action position and the detection region may be determined based on position information corresponding to the second action position and the region border parameter of the detection region. Further, the detection region may be highlighted in response to determining that the distance between the second action position and the detection region is less than or equal to the preset distance. For example, with continued reference to FIG. 2, in response to detecting that the distance between the second action position (arrow in the figure) and the detection region corresponding to the object 2 is less than or equal to the preset distance, the detection region corresponding to the object 2 may be highlighted (that is, the detection region is highlighted based on a shadow region in the figure).

S130: in response to the second action position being in the detection region, connecting the first object to the second object in the detection region in response to a second trigger operation.

The second trigger operation may be understood as a trigger operation representing the end of the connection state. Optionally, in response to the first trigger operation being a click-and-drag trigger operation, the second trigger operation may be a drag release operation; or in response to the first trigger operation being a selection trigger operation for the object to be connected, the second trigger operation may be a selection confirmation trigger operation; or in response to the first trigger operation being a parameter editing trigger operation, the second trigger operation may be an editing completion trigger operation, etc.

In the embodiments of the present disclosure, in response to the second trigger operation being detected, whether the second region is in the detection region may be determined based on the position information of the second action position and the region border parameter of the detection region. And then, in response to determining that the second action position is in the detection region, the first object may be automatically connected to the second object in the detection region, to establish the connection relationship between the first object and the second object.

For example, the execution process of the technical solutions provided by the embodiments of the present disclosure may be described by taking a drag scenario as an example. Assuming that the first trigger operation is a click-and-drag trigger operation, the second trigger operation may be a drag release operation. In response to a click trigger operation for any position being detected, the position of the click may be used as the first action position, and then the first object may be determined based on the first action position. Further, the drag trigger operation may be continued, and the second action position may be acquired during the process of performing the drag trigger operation. In addition, during the process of performing the drag operation, the second object capable of establishing a connection to the first object is determined, and then the detection element corresponding to the second object is created. Further, in response to a drag release operation being detected, position information of the last second action position acquired may be determined based on the drag release operation, and then whether the second action position is in the detection region may be determined based on the position information and the region border parameter of the detection region of the detection element. In response to the second action position being in the detection region, the first object may be connected to the second object in the detection region. For example, the first object may be connected to the second object in the detection region via a connection line.

It should be noted that in response to the second action position being in the detection region, the second object in the detection region may be highlighted. An advantage of such configuration is as follows. It helps the user more clearly and intuitively observe object content represented by the second object, such that the user can quickly locate the second object after observing the object content, thus improving the accuracy and efficiency of object connection.

It should be noted that in response to the second action position being not in the detection region, the first object is not connected to the second object in the detection region in response to the second trigger operation, and then connection failure prompt information and/or object creation prompt information is generated. The connection failure prompt information may be used to indicate that the first object and the second object are in a connection failure state. The object creation prompt information may be used to indicate whether to create a third object based on the second action position.

It should be noted that, generally, after a single connection process is performed, the detection element corresponding to the second object that has been connected to the first object may not be used again in a subsequent object connection process. In order to avoid an unnecessary resource occupying a memory of an application, after the first object is connected to the second object in the detection region, the object connection method further includes: deleting the detection element.

In the embodiments of the present disclosure, after the first object is connected to the second object, the detection element corresponding to the second object may be deleted from the memory. An advantage of such configuration is as follows. A memory space of the application is released, thereby improving running performance of the application.

It should also be noted that if the detection element is not deleted, during the process of another operation performed on the second object, detection for the performed operation needs to be performed based on the detection element, which may cause operational inconvenience. Thus, to avoid such a case, the detection element may be deleted so that the object connection operation performed in the connection state may be differentiated from another operation, and therefore, the object connection operation can be performed more accurately.

According to the technical solutions of the embodiments of the present disclosure, in response to the first trigger operation, the first action position and the second action position are acquired based on the first trigger operation. The first object to be connected can be determined based on the first action position, and then the second action position can be acquired to quickly locate, based on the second action position, the second object of the object to be connected. Then, the second object capable of establishing a connection to the first object is determined, and the detection element corresponding to the second object is created. Through creation of the detection element after the second object is determined, the effect of dynamically creating the detection element matching the second object while reducing memory usage is achieved. Because the second object is in the detection region of the detection element and the area of the detection region is greater than the area of the second object, detection for a connection operation acting on the second object is implemented in a larger range. Finally, in response to the second action position being in the detection region, the first object is connected to the second object in the detection region in response to the second trigger operation. The first object may be automatically connected to the second object without precise location to a specific point, as long as the second action position is in the detection region, thereby solving the problems of low object connection accuracy and low connection efficiency in the related art, and achieving the beneficial effects of reducing operational difficulty of object connection, improving operational experience of users, and increasing the accuracy and efficiency of object connection.

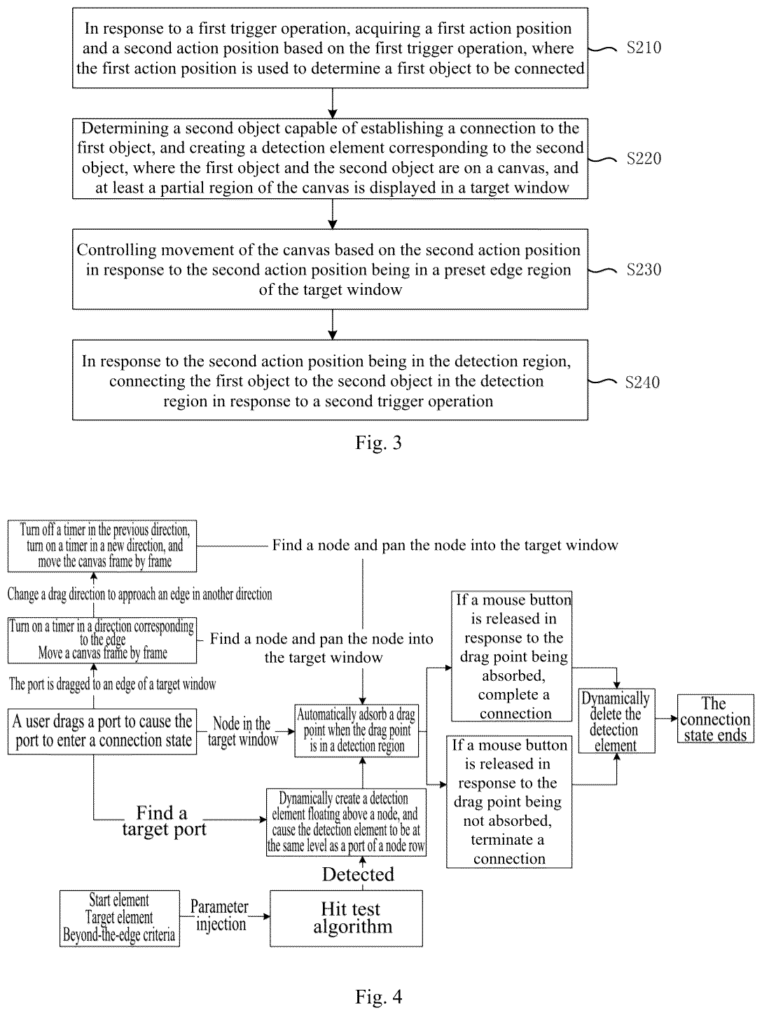

FIG. 3 is a schematic flowchart of another object connection method according to an embodiment of the present disclosure. Based on the above embodiment, according to the technical solution of the present embodiment, the first object and the second object are on a canvas, and at least a partial region of the canvas is displayed in a target window; and after acquiring the second action position, the object connection method further includes: controlling movement of the canvas based on the second action position in response to the second action position being in a preset edge region of the target window. For a specific implementation, reference may be made to the description of the present embodiment. Details about technical features that are the same as or similar to those in the foregoing embodiment are not repeated herein.

As shown in FIG. 3, the method in the present embodiment may include the following steps.

S210: in response to a first trigger operation, acquiring a first action position and a second action position based on the first trigger operation, where the first action position is used to determine a first object to be connected.

S220: determining a second object capable of establishing a connection to the first object, and creating a detection element corresponding to the second object, where the first object and the second object are on a canvas, and at least a partial region of the canvas is displayed in a target window.

The canvas may be understood as a region used to present a connection relationship between objects. The target window may be used to edit an object and visualize an editing process. In other words, the target window may be an interaction entry for performing an editing trigger operation on an object. Optionally, the editing trigger operation may include an object creation trigger operation, an object connection trigger operation, and the like. At least a partial region of the canvas being displayed in the target window may be understood as the area of the target window being less than the area of the canvas. It may also be understood that both the first object and the second object are in the target window, or the first object or the second object is in the target window, or neither the first object nor the second object is in the target window. For example, with continued reference to FIG. 2, a window 24 may be used as the target window.

It should be noted that the detection element may be created on the second object displayed in the current target window. In other words, in response to the second object being not displayed in the target window at the current moment, the detection element corresponding to the second object may not be created currently. In response to a movement operation for the canvas being performed, the second object capable of establishing a connection to the first object is displayed in the target window, and the detection element corresponding to the second object may be created. An advantage of such configuration is as follows. The effect of dynamically creating the detection element matching the second object while reducing memory usage is achieved.

S230: controlling movement of the canvas based on the second action position in response to the second action position being in a preset edge region of the target window.

The preset edge region may be a region determined based on a window border of the target window and any border inside the window. In the embodiments of the present disclosure, the target window may be scaled according to a preset scale, to obtain a target border with a border size less than a border size of the target window, and then the target border is placed in a central region of the target window, such that the target border and the target window are in a concentric state. Further, the preset edge region may be determined based on the target window and the target border. Optionally, a region between the target window and the target border may be used as the preset edge region, i.e., a region between the window border of the target window and borders of the target border. Alternatively, for each border of the target border, a perpendicular line may be drawn from two endpoints of the border to a window border closest to the border. Further, a region constructed based on two perpendicular lines, the window border, and the border may be used as the preset edge region, to obtain four preset edge regions. It should be noted that the movement direction of the canvas is associated with a direction of the second action position relative to the first action position. That is, the movement direction of the canvas may be a direction getting close to the second action position and getting away from the first action position.

In practical application, during the process of performing an object connection operation based on the target window, the position of the second object to be connected may be outside the target window. In this case, in order to successfully connect the first object and the second object, the user needs to stop performing the first trigger operation, and then manually drag or scale the target window to cause the second object to be inside the target window; until then, the first trigger operation cannot be performed again. As such, operation steps may be cumbersome, and the user may repeatedly perform the same operation, resulting in reduced the efficiency of object connection.

With respect to the above case, in the embodiments of the present disclosure, after the second action position is acquired, in response to determining that the second action position is in the preset edge region of the target window based on the position information of the second action position and the region position information of the preset edge region, it may indicate that the second action position is close to the window border of the target window. In this case, in order to enable the first trigger operation to be performed continuously, the movement of the canvas may be controlled based on the second action position, such that the canvas moves along a movement trend of the second action position.

It should be noted that, in response to the second action position being in the preset edge region of the target window, the second object to be connected may be in the preset edge region. Thus, in order to avoid movement of the canvas occurring with the second object being in the preset edge region, in response to detecting that the second action position is in the preset edge region of the target window, detection for duration of the second action position staying in the preset edge region may be performed before the canvas is controlled to move. Further, in response to detecting that the staying duration reaches preset duration, the canvas may be controlled to move based on the second action position. in response to detecting that the staying duration reaches preset duration, the canvas may be controlled to move based on the second action position.

In the embodiments of the present disclosure, the movement information of the canvas is associated with the distance between the second action position and the window border of the target window. Optionally, the movement information includes at least a movement direction and/or a movement speed. That is, the movement information of the canvas may be determined based on the distance between the second action position and the window border of the target window.

Optionally, in response to the movement information including the movement direction, the distance between the second action position and each window border of the target window may be determined to obtain a plurality of distances. Further, a target distance less than or equal to a preset threshold may be determined from the plurality of distances, and then a window border corresponding to the target distance may be used as the target border. Furthermore, the movement direction of the canvas may be determined based on a direction corresponding to the target border.

Optionally, in response to the movement information including the movement speed, the distance is negatively correlated with the movement speed. The distance between the second action position and the target border may be periodically or continuously determined during the process of controlling the canvas to move in the determined movement direction. A small distance may indicate that the second action position in this case may be adjacent to a position that satisfies a user need, and therefore, the movement of the canvas may be slowed down. A large distance may indicate that the second action position in this case is far away from the position that satisfies the user need, and therefore, the movement of the canvas may be sped up. An advantage of such configuration is as follows. It conforms to an operation habit of the user, which helps the user control the movement speed of the canvas and thus improves user experience.

In the embodiments of the present disclosure, controlling the movement of the canvas based on the second action position may be determining the movement direction of the canvas based on the second action position. Further, the canvas is controlled to move in the movement direction.

Optionally, controlling movement of the canvas based on the second action position includes: determining a target border based on the distance between the second action position and each window border of the target window, determining the movement direction of the canvas based on a direction corresponding to the target border, and controlling the canvas to move in the movement direction.

In the embodiments of the present disclosure, the distance between the second action position and each window border may be determined based on the position information of the second action position and the border position information of the window border of the target window, to obtain a plurality of distances. Further, a target distance less than or equal to a preset threshold may be determined from the plurality of distances, and then a window border corresponding to the target distance may be used as the target border. The direction corresponding to the target border may represent a relative direction of the target border in a window border. For example, assuming that the window border is a rectangular border, directions corresponding to the target border may include up, down, left, and right.

As an optional implementation of the embodiments of the present disclosure, the distance between the second action position and each window border of the target window is determined, then the target distance less than or equal to the preset threshold is determined from the plurality of distances, and the window border corresponding to the target distance is used as the target border. Further, the direction corresponding to the target border may be determined, then the movement direction of the canvas may be determined based on the direction corresponding to the target border, and the canvas may be controlled to move in the movement direction. An advantage of such configuration is as follows. The effect of determining the movement direction of the canvas based on the distance between the second action position and the window border is achieved, so that the finally determined movement direction of the canvas satisfies the user need, and the flexibility of the movement operation performed on the canvas is enhanced.

It should be noted that one or more target borders may be finally determined. Different numbers of target borders may correspond to different methods of determining the movement direction. The two cases may be separately described below.

Optionally, in response to that there is one target border, the direction corresponding to the target border is used as the movement direction of the canvas.

In the embodiments of the present disclosure, in response to that there is one target border, the direction corresponding to the target border may be used as the movement direction of the canvas. For example, assuming that one target border is finally determined and the relative direction of the target border in the target window is left, the movement direction of the canvas may be determined as left, and then the canvas is controlled to move to the left.

Optionally, in response to that there are a plurality of target borders, directions corresponding to the plurality of target borders are superimposed to obtain the movement direction of the canvas.

In the embodiments of the present disclosure, in response to that there are a plurality of target borders, the direction corresponding to each target border may be determined. Further, the directions corresponding to the plurality of target borders may be superimposed, and then the direction obtained by superimposition may be used as the movement direction of the canvas.

It should be noted that the directions may be superimposed through a variety of methods. Optionally, an initial direction parameter may be preset for the direction corresponding to each window border, and then a direction parameter corresponding to each combined direction may be determined based on a plurality of initial direction parameters. Further, in response to a plurality of target borders being determined, an initial direction parameter of the direction corresponding to each target border may be obtained, and then a plurality of initial direction parameters may be superimposed to obtain the direction parameter. Furthermore, the combined direction corresponding to the direction parameter may be used as the movement direction of the canvas. The initial direction parameter may be any value, as long as a sum of at least two initial direction parameters is a unique value. For example, an initial direction parameter of a left direction corresponding to the window border may be set to 1; an initial direction parameter of a right direction corresponding to the window border may be set to 2; an initial direction parameter of an up direction corresponding to the window border may be set to 4; and an initial direction parameter of a down direction corresponding to the window border may be set to 8. The combined direction may be understood as a direction obtained by combining two adjacent directions. For example, in response to directions corresponding to the window border including up, down, left, and right directions and corresponding initial direction parameters being respectively 4, 8, 1, and 2, the combined directions may include upper left, upper right, lower right, and lower left, and corresponding direction parameters are respectively 5, 6, 10, and 9.

For example, with continued reference to the above example, assuming that there are two target borders, and the directions corresponding to each target border is right and up, the corresponding initial direction parameters are 2 and 4, respectively. Further, the two initial direction parameters may be superimposed to obtain the direction parameter of the combined direction, which is 6. Furthermore, the combined direction may be determined as upper right based on the direction parameter.

In the embodiments of the present disclosure, the movement of the canvas may be controlled based on the second action position through a variety of methods. Optionally, in order to reduce impact of a canvas panning operation on performance of the application, a timer may be used to control the movement of the canvas based on the second action position.

Optionally, controlling movement of the canvas based on the second action position includes: determining the movement direction of the canvas based on the second action position, and creating a timer in the movement direction, where the timer is used to send a trigger signal based on a preset frequency; updating the second action position based on the trigger signal, and determining the movement speed and the movement direction of the canvas based on an updated second action position; and in response to that the movement direction remains unchanged, controlling the canvas to move at the movement speed in the movement direction.

The timer may be a mechanism used for executing code or repeatedly executing code after a specific time interval. The function of the timer may be implemented by means of a script including a timer function. The preset frequency may be a signal sending frequency preset in the timer. The preset frequency may be set based on a default parameter, or may be customized by the user. The trigger signal may be understood as a signal triggering the canvas panning operation.

In the embodiments of the present disclosure, the movement direction of the canvas may be determined based on the second action position, and the timer may be created in the movement direction, to send the trigger signal by the timer based on the preset frequency. Further, in response to the timer sending the trigger signal, the movement of the canvas may be controlled based on the trigger signal, and during the process of moving the canvas, the position information of the second action position may be acquired in real time, to update the second action position based on the acquired position information. Further, the target border may be determined based on the distance between the updated second action position and each window border of the target window, the movement direction of the canvas may be determined based on the direction corresponding to the target border, and the movement speed of the canvas may be determined based on the distance between the updated second action position and the target border. In addition, the movement direction may be detected to determine whether the movement direction changes. Further, in response to that the movement direction remains unchanged, the canvas may be controlled to move based on the movement direction and the movement speed that are determined based on the updated second action position.

Optionally, after the movement speed and the movement direction of the canvas are determined based on the updated second action position, the object connection method further includes: in response to that the movement direction changes, turning off the timer created in the movement direction before the change, and creating a timer in a movement direction after the change.

In the embodiments of the present disclosure, in response to that the movement direction changes, in order to control the canvas to move in the movement direction after the change, the timer created in the movement direction before the change may be turned off, then a timer is created in the movement direction after the change to send the trigger signal by the timer based on the preset frequency, and in response to the trigger signal being received, the canvas is controlled to move in the movement direction after the change. An advantage of such configuration is as follows. The effect of dynamically adjusting the movement direction of the canvas based on position change information of the second action position is achieved, ensuring the effect of moving the canvas always in the movement direction used when a timer is created.

S240: in response to the second action position being in the detection region, connecting the first object to the second object in the detection region in response to a second trigger operation.

It should be noted that in response to the first object and the second object being on the canvas and at least a partial region of the canvas being displayed in the target window, an overall process of executing the technical solution provided by the embodiments of the present disclosure may include: displaying the target window, where at least a partial region of the canvas is displayed in the target window, and the canvas includes at least two objects available for connection; in response to the first trigger operation, acquiring the first action position in the target window, and determining, based on the first action position, the first object to be connected from the objects available for connection; determining the second object capable of establishing a connection to the first object from the objects available for connection, and determining the detection element corresponding to the second object; and acquiring the second action position in the target window in response to the second trigger operation, and connecting the first object to the second object in response to the second action position being in the detection region.

The second object is in the detection region of the detection element, and the area of the detection region is greater than the area of the second object. The object available for connection may be understood as an object capable of establishing a connection to another object.

In the embodiments of the present disclosure, the target window may be displayed based on a display interface, at least a partial region of the canvas may be displayed in the target window, and the canvas may include at least two objects available for connection. Further, in response to the first trigger operation input for any position in the target window being detected, the first action position may be acquired based on the first trigger operation, and the first action position may be respectively matched with each object available for connection, to determine an object matching the first action position among the objects available for connection and use the object as the first object. Further, the second object capable of establishing a connection to the first object may be determined from the plurality of objects available for connection based on pre-stored object correspondence information or type correspondence information. In addition, the detection element corresponding to the second object may be created so that the second object is in the detection region of the detection element. Further, in response to the second trigger operation being detected, the second action position may be acquired based on the second trigger operation. In addition, whether the second action position is in the detection region may be determined. Further, the first object is connected to the second object in response to the second action position being in the detection region.

According to the technical solutions of the embodiments of the present disclosure, the second object capable of establishing a connection to the first object is determined, and the detection element corresponding to the second object is created, where the first object and the second object are on the canvas, and at least a partial region of the canvas is displayed in the target window. Further, the movement of the canvas is controlled based on the second action position in response to the second action position being in the preset edge region of the target window, achieving the effect of controlling automatic movement of the canvas in a corresponding direction in response to the second action position being in the edge region of the window and thus dynamically adjusting a display region of the canvas in the window.

FIG. 4 is a schematic flowchart of an object connection method according to an embodiment of the present disclosure. The present embodiment is an optional embodiment of the present disclosure. The object connection method may be described by using an example in which the first object and the second object are port identifiers of one or more graphic elements in a graphic editing tool. As shown in FIG. 4, the process of performing the method provided in the present embodiment of the present disclosure may be as follows.

First, the user inputs a click and drag operation for a port, so that the port to be connected enters a connection state, and then a drag is performed in a target window to obtain a drag point. Further, a target port capable of establishing a connection to the port to be connected is determined, and a detection element floating above a node is dynamically created and caused to be at the same level as a port of a node row. Then the drag point is automatically adsorbed in response to the drag point being in a detection region of the detection element. Further, if a mouse button is released in response to the drag point being adsorbed, the port to be connected can be connected to the target port; alternatively, the connection is terminated if the mouse button is released in response to the drag point being not adsorbed.

It should be noted that a start element, a target element, and a beyond-the-edge criteria may be acquired during the process of creating the detection element floating above the node, and then acquired parameters are injected into a hit test algorithm. Further, detection is performed based on the hit test algorithm to obtain the detection element, where the area of the detection region of the detection element is greater than the area of the node row.

In response to the port being dragged to an edge of the target window, a timer in a direction corresponding to the window edge may be turned on, and movement of a canvas is controlled frame by frame, where location of a node where the target port is located is performed during the movement, and the node is panned into the target window. Further, in response to a drag direction being changed to approach an edge in another direction, the timer in the previous direction may be turned off, a timer in a new direction may be turned on, and the movement of the canvas may continue to be controlled frame by frame, where location of a node corresponding to the target port is performed during the movement, and the node is panned into the target window.

According to the technical solutions of this embodiments of the present disclosure, in response to the first trigger operation, the first action position and the second action position are acquired based on the first trigger operation, where the first action position is used to determine the first object to be connected, thereby achieving the effect of determining an action position based on a trigger operation and then quickly locating, based on the action position, the object to be connected. Further, the second object capable of establishing a connection to the first object is determined, and the detection element corresponding to the second object is created, where the second object is in the detection region of the detection element, and the area of the detection region is greater than the area of the second object. Through creation of the detection element after the second object is determined, the effect of dynamically creating the detection element matching the second object while reducing memory usage is achieved. Further, in response to the second action position being in the detection region, the first object is connected to the second object in the detection region in response to the second trigger operation, thereby solving the problems of low object connection accuracy and low connection efficiency in the related art, and achieving the beneficial effects of reducing operational difficulty of object connection, improving operational experience of users, and increasing the accuracy and efficiency of object connection.

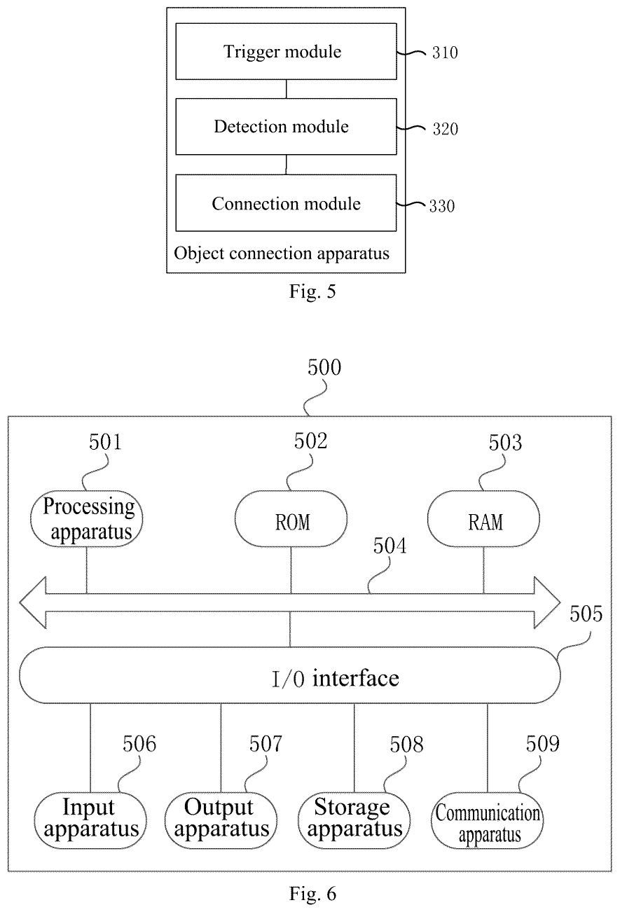

FIG. 5 is a schematic diagram of a structure of an object connection apparatus according to an embodiment of the present disclosure. As shown in FIG. 5, the apparatus includes a trigger module 310, a detection module 320, and a connection module 330.

The trigger module 310 is configured to, in response to a first trigger operation, acquire a first action position and a second action position based on the first trigger operation, where the first action position is used to determine a first object to be connected. The detection module 320 is configured to determine a second object capable of establishing a connection to the first object, and create a detection element corresponding to the second object, where the second object is in a detection region of the detection element, and the area of the detection region is greater than the area of the second object. The connection module 330 is configured to, in response to the second action position being in the detection region, connect the first object to the second object in the detection region in response to a second trigger operation.

According to the technical solutions of the embodiments of the present disclosure, in response to the first trigger operation, the trigger module 310 acquires the first action position and the second action position based on the first trigger operation. The first object to be connected can be determined based on the first action position, and then the second action position can be acquired to quickly locate, based on the second action position, the second object of the object to be connected. Then, the detection module 320 determines the second object capable of establishing a connection to the first object, and creates the detection element corresponding to the second object. Through creation of the detection element after the second object is determined, the effect of dynamically creating the detection element matching the second object while reducing memory usage is achieved. Because the second object is in the detection region of the detection element and the area of the detection region is greater than the area of the second object, detection for a connection operation acting on the second object is implemented in a larger range. Finally, in response to the second action position being in the detection region, the connection module 330 connects the first object to the second object in the detection region in response to the second trigger operation. The first object may be automatically connected to the second object without precise location to the interior of the border of the second object, as long as the second action position is in the detection region, thereby solving the problems of low object connection accuracy and low connection efficiency in the related art, and achieving the beneficial effects of reducing operational difficulty of object connection, improving operational experience of users, and increasing the accuracy and efficiency of object connection.

On the basis of the above optional technical solutions, optionally, the detection module 320 includes an element creation unit. The element creation unit is configured to: determine an object border parameter corresponding to the second object, generate, based on the object border parameter, a region border parameter for determining the detection region corresponding to the second object, and create the detection element corresponding to the second object based on the region border parameter.

On the basis of the above optional technical solutions, optionally, the apparatus further includes a highlighting module. The highlighting module is configured to, after the detection element corresponding to the second object is created, highlight the detection region in response to a distance between the second action position and the detection region being less than or equal to a preset distance.

On the basis of the above optional technical solutions, optionally, the apparatus further includes an element deletion module. The element deletion module is configured to delete the detection element after the first object is connected to the second object in the detection region.

On the basis of the above optional technical solutions, optionally, the first object and the second object are on a canvas, and at least a partial region of the canvas is displayed in a target window; and the apparatus further includes a canvas control module. The canvas control module is configured to, after the second action position is acquired, control movement of the canvas based on the second action position in response to the second action position being in a preset edge region of the target window.

On the basis of the above optional technical solutions, optionally, movement information of the canvas is associated with a distance between the second action position and a window border of the target window, and the movement information includes at least one of a movement direction and a movement speed.

On the basis of the above optional technical solutions, optionally, the canvas control module is configured to: determine a target border based on a distance between the second action position and each window border of the target window, determine the movement direction of the canvas based on a direction corresponding to the target border, and control the canvas to move in the movement direction.

On the basis of the above optional technical solutions, optionally, the canvas control module includes a first movement direction determination unit and/or a second movement direction determination unit. The first movement direction determination unit is configured to, in response to that there is one target border, use the direction corresponding to the target border as the movement direction of the canvas; and the second movement direction determination unit is configured to, in response to that there are a plurality of target borders, superimpose directions corresponding to the plurality of target borders to obtain the movement direction of the canvas.

On the basis of the above optional technical solutions, optionally, the canvas control module includes a timer creation unit, a position update unit, and a canvas control unit. The timer creation unit is configured to determine a movement direction of the canvas based on the second action position, and create a timer in the movement direction, where the timer is used to send a trigger signal based on a preset frequency. The position update unit is configured to update the second action position based on the trigger signal, and determine a movement speed and the movement direction of the canvas based on an updated second action position. The canvas control unit is configured to, in response to that the movement direction remains unchanged, control the canvas to move at the movement speed in the movement direction.

On the basis of the above optional technical solutions, optionally, the apparatus further includes a timer creation module. The timer creation module is configured to, after the movement speed and the movement direction of the canvas are determined based on the updated second action position, in response to that the movement direction changes, turn off the timer created in the movement direction before the change, and create a timer in a movement direction after the change.

On the basis of the above optional technical solutions, optionally, the first object and the second object are port identifiers of one or more graphic elements in a graphic editing tool.

The object connection apparatus according to this embodiment of the present disclosure can perform the object connection method according to any one of the embodiments of the present disclosure, and has corresponding functional modules and beneficial effects for performing the method.

It is worth noting that the units and modules included in the above apparatus are obtained through division merely according to functional logic, but are not limited to the above division, as long as corresponding functions can be implemented. In addition, specific names of the functional units are merely used for mutual distinguishing, and are not used to limit the protection scope of the embodiments of the present disclosure.

FIG. 6 is a schematic diagram of a structure of an electronic device according to an embodiment of the present disclosure. Reference is made to FIG. 6 below, which is a schematic diagram of a structure of an electronic device 500 (such as a terminal device or a server in FIG. 6) suitable for implementing embodiments of the present disclosure. The terminal device in this embodiment of the present disclosure may include, but is not limited to, mobile terminals such as a mobile phone, a notebook computer, a digital broadcast receiver, a personal digital assistant (PDA), a PAD (tablet computer), a portable multimedia player (PMP), and a vehicle-mounted terminal (such as a vehicle navigation terminal), and fixed terminals such as a digital TV and a desktop computer. The electronic device shown in FIG. 6 is merely an example, and shall not impose any limitation on the function and scope of use of the embodiments of the present disclosure.

As shown in FIG. 6, the electronic device 500 may include a processing apparatus (e.g., a central processing unit or a graphics processing unit) 501 that may perform a variety of appropriate actions and processing in accordance with a program stored in a read-only memory (ROM) 502 or a program loaded from a storage apparatus 508 into a random access memory (RAM) 503. The RAM 503 further stores various programs and data required for the operation of the electronic device 500. The processing apparatus 501, the ROM 502, and the RAM 503 are connected to each other through a bus 504. An input/output (I/O) interface 505 is also connected to the bus 504.

Generally, the following apparatuses may be connected to the I/O interface 505: an input apparatus 506 including, for example, a touchscreen, a touchpad, a keyboard, a mouse, a camera, a microphone, an accelerometer, and a gyroscope; an output apparatus 507 including, for example, a liquid crystal display (LCD), a speaker, and a vibrator; the storage apparatus 508 including, for example, a tape and a hard disk; and a communication apparatus 509. The communication apparatus 509 may allow the electronic device 500 to perform wireless or wired communication with other devices to exchange data. Although FIG. 6 shows the electronic device 500 having various apparatuses, it should be understood that it is not required to implement or have all of the shown apparatuses. It may be an alternative to implement or have more or fewer apparatuses.

In particular, according to an embodiment of the present disclosure, the process described above with reference to the flowchart may be implemented as a computer software program. For example, this embodiment of the present disclosure includes a computer program product, which includes a computer program carried on a non-transitory computer-readable medium, where the computer program includes program code for performing the method shown in the flowchart. In such an embodiment, the computer program may be downloaded from a network through the communication apparatus 509 and installed, installed from the storage apparatus 508, or installed from the ROM 502. When the computer program is executed by the processing apparatus 501, the above-mentioned functions defined in the method of the embodiment of the present disclosure are performed.

The names of messages or information exchanged between a plurality of apparatuses in the implementations of the present disclosure are used for illustrative purposes only, and are not used to limit the scope of these messages or information.

The electronic device according to this embodiment of the present disclosure and the object connection method according to the above embodiments belong to the same inventive concept. For the technical details not exhaustively according to this embodiment, reference may be made to the above embodiments, and this embodiment and the above embodiments have the same beneficial effects.

An embodiment of the present disclosure provides a computer storage medium storing a computer program thereon, where the program, when executed by a processor, implements the object connection method according to the above embodiments.

It should be noted that the above computer-readable medium described in the present disclosure may be a computer-readable signal medium, a computer-readable storage medium, or any combination thereof. The computer-readable storage medium may be, for example but not limited to, electric, magnetic, optical, electromagnetic, infrared, or semiconductor systems, apparatuses, or devices, or any combination thereof. A more specific example of the computer-readable storage medium may include, but is not limited to: an electrical connection having one or more wires, a portable computer magnetic disk, a hard disk, a random access memory (RAM), a read-only memory (ROM), an erasable programmable read-only memory (EPROM) (or a flash memory), an optical fiber, a portable compact disc read-only memory (CD-ROM), an optical storage device, a magnetic storage device, or any suitable combination thereof. In the present disclosure, the computer-readable storage medium may be any tangible medium containing or storing a program which may be used by or in combination with an instruction execution system, apparatus, or device. In the present disclosure, the computer-readable signal medium may include a data signal propagated in a baseband or as a part of a carrier, the data signal carrying computer-readable program code. The propagated data signal may be in various forms, including but not limited to an electromagnetic signal, an optical signal, or any suitable combination thereof. The computer-readable signal medium may also be any computer-readable medium other than the computer-readable storage medium. The computer-readable signal medium can send, propagate, or transmit a program used by or in combination with an instruction execution system, apparatus, or device. The program code contained in the computer-readable medium may be transmitted by any suitable medium, including but not limited to: electric wires, optical cables, radio frequency (RF), etc., or any suitable combination thereof.

In some implementations, the client and the server may communicate using any currently known or future-developed network protocol such as a Hypertext Transfer Protocol (HTTP), and may be connected to digital data communication (for example, communication network) in any form or medium. Examples of the communication network include a local area network (“LAN”), a wide area network (“WAN”), an internetwork (for example, the Internet), a peer-to-peer network (for example, an ad hoc peer-to-peer network), and any currently known or future-developed network.

The above computer-readable medium may be contained in the above electronic device. Alternatively, the computer-readable medium may exist independently, without being assembled into the electronic device.

The above computer-readable medium carries one or more programs that, when executed by the electronic device, cause the electronic device to: in response to a first trigger operation, acquire a first action position and a second action position based on the first trigger operation, where the first action position is used to determine a first object to be connected; determine a second object capable of establishing a connection to the first object, and create a detection element corresponding to the second object, where the second object is in a detection region of the detection element, and the area of the detection region is greater than the area of the second object; and in response to the second action position being in the detection region, connect the first object to the second object in the detection region in response to a second trigger operation.

Computer program code for performing operations of the present disclosure can be written in one or more programming languages or a combination thereof, where the programming languages include but are not limited to object-oriented programming languages, such as Java, Smalltalk, and C++, and further include conventional procedural programming languages, such as “C” language or similar programming languages. The program code may be completely executed on a computer of a user, partially executed on a computer of a user, executed as an independent software package, partially executed on a computer of a user and partially executed on a remote computer, or completely executed on a remote computer or server. In the case of the remote computer, the remote computer may be connected to the computer of the user through any kind of network, including a local area network (LAN) or a wide area network (WAN), or may be connected to an external computer (for example, connected through the Internet with the aid of an Internet service provider).

The flowchart and block diagram in the accompanying drawings illustrate the possibly implemented architecture, functions, and operations of the system, method, and computer program product according to various embodiments of the present disclosure. In this regard, each block in the flowchart or block diagram may represent a module, program segment, or part of code, and the module, program segment, or part of code contains one or more executable instructions for implementing the specified logical functions. It should also be noted that, in some alternative implementations, the functions marked in the blocks may also occur in an order different from that marked in the accompanying drawings. For example, two blocks shown in succession can actually be performed substantially in parallel, or they can sometimes be performed in the reverse order, depending on the functions involved. It should also be noted that each block in the block diagram and/or the flowchart, and a combination of the blocks in the block diagram and/or the flowchart may be implemented by a dedicated hardware-based system that executes specified functions or operations, or may be implemented by a combination of dedicated hardware and computer instructions.

The related units described in the embodiments of the present disclosure may be implemented by software, or may be implemented by hardware. Names of the units do not constitute a limitation on the units in some cases. For example, the trigger module may alternatively be described as “a module for obtaining a first action position and a second action position”.

The functions described herein above may be performed at least partially by one or more hardware logic components. For example, without limitation, exemplary types of hardware logic components that may be used include: a field programmable gate array (FPGA), an application-specific integrated circuit (ASIC), an application-specific standard product (ASSP), a system-on-chip (SOC), a complex programmable logic device (CPLD), and the like.

In the context of the present disclosure, a machine-readable medium may be a tangible medium that may contain or store a program used by or in combination with an instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination thereof. More specific examples of the machine-readable storage medium may include an electrical connection based on one or more wires, a portable computer disk, a hard disk, a random access memory (RAM), a read-only memory (ROM), an erasable programmable read-only memory (EPROM) (or a flash memory), an optic fiber, a portable compact disc read-only memory (CD-ROM), an optical storage device, a magnetic storage device, or any suitable combination thereof.

According to one or more embodiments of the present disclosure, example 1 provides an object connection method, including: in response to a first trigger operation, acquiring a first action position and a second action position based on the first trigger operation, where the first action position is used to determine a first object to be connected; determining a second object capable of establishing a connection to the first object, and creating a detection element corresponding to the second object, where the second object is in a detection region of the detection element, and the area of the detection region is greater than the area of the second object; and in response to the second action position being in the detection region, connecting the first object to the second object in the detection region in response to a second trigger operation.

According to one or more embodiments of the present disclosure, example 2 provides a method of example 1. Optionally, creating the detection element corresponding to the second object includes: determining an object border parameter corresponding to the second object, generating, based on the object border parameter, a region border parameter for determining the detection region corresponding to the second object, and creating the detection element corresponding to the second object based on the region border parameter.

According to one or more embodiments of the present disclosure, example 3 provides a method of example 1. Optionally, after the creating the detection element corresponding to the second object, the method further includes: highlighting the detection region in response to a distance between the second action position and the detection region being less than or equal to a preset distance.

According to one or more embodiments of the present disclosure, example 4 provides a method of example 1. Optionally, after the connecting the first object to the second object in the detection region, the method further includes deleting the detection element.

According to one or more embodiments of the present disclosure, example 5 provides a method of example 1. Optionally, the first object and the second object are on a canvas, and at least a partial region of the canvas is displayed in a target window; and after acquiring the second action position, the method further includes: controlling movement of the canvas based on the second action position in response to the second action position being in a preset edge region of the target window.

According to one or more embodiments of the present disclosure, example 6 provides a method of example 5. Optionally, movement information of the canvas is associated with a distance between the second action position and a window border of the target window; and the movement information includes at least one of a movement direction and a movement speed.

According to one or more embodiments of the present disclosure, example 7 provides a method of example 6. Optionally, the controlling movement of the canvas based on the second action position includes: determining a target border based on a distance between the second action position and each window border of the target window, determining the movement direction of the canvas based on a direction corresponding to the target border, and controlling the canvas to move in the movement direction.

According to one or more embodiments of the present disclosure, example 8 provides a method of example 7. Optionally, the determining the movement direction of the canvas based on the direction corresponding to the target border includes at least one of: (i) in response to that there is one target border, using the direction corresponding to the target border as the movement direction of the canvas; (ii) in response to that there are a plurality of target borders, superimposing directions corresponding to the plurality of target borders to obtain the movement direction of the canvas.

According to one or more embodiments of the present disclosure, example 9 provides a method of example 5. Optionally, the controlling movement of the canvas based on the second action position includes: determining a movement direction of the canvas based on the second action position, and creating a timer in the movement direction, where the timer is used to send a trigger signal based on a preset frequency; updating the second action position based on the trigger signal, and determining a movement speed and the movement direction of the canvas based on an updated second action position; and in response to that the movement direction remains unchanged, controlling the canvas to move at the movement speed in the movement direction.

According to one or more embodiments of the present disclosure, example 10 provides a method of example 9. Optionally, after determining the movement speed and the movement direction of the canvas based on the updated second action position, the method further includes: in response to that the movement direction changes, turning off the timer created in the movement direction before the change, and creating a timer in a movement direction after the change.

According to one or more embodiments of the present disclosure, example 11 provides a method of example 1. Optionally, the first object and the second object are port identifiers of one or more graphic elements in a graphic editing tool.

According to one or more embodiments of the present disclosure, example 12 provides an object connection apparatus. The apparatus includes: a trigger module configured to, in response to a first trigger operation, acquire a first action position and a second action position based on the first trigger operation, where the first action position is used to determine a first object to be connected; a detection module configured to determine a second object capable of establishing a connection to the first object, and create a detection element corresponding to the second object, where the second object is in a detection region of the detection element, and the area of the detection region is greater than the area of the second object; and a connection module configured to, in response to the second action position being in the detection region, connect the first object to the second object in the detection region in response to a second trigger operation.

The foregoing descriptions are merely preferred embodiments of the present disclosure and explanations of the applied technical principles. Those skilled in the art should understand that the scope of disclosure involved in the present disclosure is not limited to the technical solutions formed by specific combinations of the foregoing technical features, and shall also cover other technical solutions formed by any combination of the foregoing technical features or equivalent features thereof without departing from the foregoing concept of disclosure. For example, a technical solution formed by a replacement of the foregoing features with technical features with similar functions disclosed in the present disclosure (but not limited thereto) also falls within the scope of the present disclosure.

In addition, although the various operations are depicted in a specific order, it should not be construed as requiring these operations to be performed in the specific order shown or in a sequential order. Under certain circumstances, multitasking and parallel processing may be advantageous. Similarly, although several specific implementation details are included in the foregoing discussions, these details should not be construed as limiting the scope of the present disclosure. Some features that are described in the context of separate embodiments can also be implemented in combination in a single embodiment. In contrast, various features described in the context of a single embodiment may alternatively be implemented in a plurality of embodiments individually or in any suitable sub-combination.

Although the subject matter has been described in a language specific to structural features and/or logical actions of the method, it should be understood that the subject matter defined in the appended claims is not necessarily limited to the specific features or actions described above. In contrast, the specific features and actions described above are merely exemplary forms of implementing the claims.

1. An object connection method, comprising:
in response to a first trigger operation, acquiring a first action position and a second action position based on the first trigger operation, wherein the first action position is used to determine a first object to be connected;
determining a second object capable of establishing a connection to the first object, and creating a detection element corresponding to the second object, wherein the second object is in a detection region of the detection element, and an area of the detection region is greater than an area of the second object; and
in response to the second action position being in the detection region, connecting the first object to the second object in the detection region in response to a second trigger operation.

2. The object connection method according to claim 1, wherein the creating the detection element corresponding to the second object comprises:
determining an object border parameter corresponding to the second object, generating, based on the object border parameter, a region border parameter for determining the detection region corresponding to the second object, and creating the detection element corresponding to the second object based on the region border parameter.

3. The object connection method according to claim 1, wherein after the creating the detection element corresponding to the second object, the object connection method further comprises:
highlighting the detection region in response to a distance between the second action position and the detection region being less than or equal to a preset distance.

4. The object connection method according to claim 1, wherein after the connecting the first object to the second object in the detection region, the object connection method further comprises:
deleting the detection element.

5. The object connection method according to claim 1, wherein the first object and the second object are on a canvas, and at least a partial region of the canvas is displayed in a target window; and after the acquiring the second action position, the object connection method further comprises:
controlling movement of the canvas based on the second action position in response to the second action position being in a preset edge region of the target window.

6. The object connection method according to claim 5, wherein movement information of the canvas is associated with a distance between the second action position and a window border of the target window, and the movement information comprises at least one of a movement direction and a movement speed.

7. The object connection method according to claim 6, wherein the controlling movement of the canvas based on the second action position comprises:
determining a target border based on a distance between the second action position and each window border of the target window, determining the movement direction of the canvas based on a direction corresponding to the target border, and controlling the canvas to move in the movement direction.

8. The object connection method according to claim 7, wherein the determining the movement direction of the canvas based on the direction corresponding to the target border comprises at least one of:
(i) in response to that there is one target border, using the direction corresponding to the target border as the movement direction of the canvas;
(ii) in response to that there are a plurality of target borders, superimposing directions corresponding to the plurality of target borders to obtain the movement direction of the canvas.

9. The object connection method according to claim 5, wherein the controlling movement of the canvas based on the second action position comprises:
determining a movement direction of the canvas based on the second action position, and creating a timer in the movement direction, wherein the timer is used to send a trigger signal based on a preset frequency;
updating the second action position based on the trigger signal, and determining a movement speed and the movement direction of the canvas based on an updated second action position; and
in response to that the movement direction remains unchanged, controlling the canvas to move at the movement speed in the movement direction.

10. The object connection method according to claim 9, wherein after determining the movement speed and the movement direction of the canvas based on the updated second action position, the object connection method further comprises:
in response to that the movement direction changes, turning off the timer created in the movement direction before the change, and creating a timer in a movement direction after the change.

11. The object connection method according to claim 1, wherein the first object and the second object are port identifiers of one or more graphic elements in a graphic editing tool.

12. An electronic device, comprising:
one or more processors; and
a storage apparatus configured to store one or more programs, wherein
the one or more programs, when executed by the one or more processors, cause the one or more processors to implement an object connection method, and the object connection method comprises:
in response to a first trigger operation, acquiring a first action position and a second action position based on the first trigger operation, wherein the first action position is used to determine a first object to be connected;
determining a second object capable of establishing a connection to the first object, and creating a detection element corresponding to the second object, wherein the second object is in a detection region of the detection element, and an area of the detection region is greater than an area of the second object; and
in response to the second action position being in the detection region, connecting the first object to the second object in the detection region in response to a second trigger operation.

13. The electronic device according to claim 12, wherein the creating the detection element corresponding to the second object comprises:
determining an object border parameter corresponding to the second object, generating, based on the object border parameter, a region border parameter for determining the detection region corresponding to the second object, and creating the detection element corresponding to the second object based on the region border parameter.

14. The electronic device according to claim 12, wherein after the creating the detection element corresponding to the second object, the object connection method further comprises:
highlighting the detection region in response to a distance between the second action position and the detection region being less than or equal to a preset distance.

15. The electronic device according to claim 12, wherein after the connecting the first object to the second object in the detection region, the object connection method further comprises:
deleting the detection element.

16. The electronic device according to claim 12, wherein the first object and the second object are on a canvas, and at least a partial region of the canvas is displayed in a target window; and after the acquiring the second action position, the object connection method further comprises:
controlling movement of the canvas based on the second action position in response to the second action position being in a preset edge region of the target window.

17. The electronic device according to claim 16, wherein movement information of the canvas is associated with a distance between the second action position and a window border of the target window, and the movement information comprises at least one of a movement direction and a movement speed.

18. The electronic device according to claim 17, wherein the controlling movement of the canvas based on the second action position comprises:
determining a target border based on a distance between the second action position and each window border of the target window, determining the movement direction of the canvas based on a direction corresponding to the target border, and controlling the canvas to move in the movement direction.

19. The electronic device according to claim 18, wherein the determining the movement direction of the canvas based on the direction corresponding to the target border comprises at least one of:
(i) in response to that there is one target border, using the direction corresponding to the target border as the movement direction of the canvas;
(ii) in response to that there are a plurality of target borders, superimposing directions corresponding to the plurality of target borders to obtain the movement direction of the canvas.

20. A storage medium comprising computer-executable instructions, wherein the computer-executable instructions, when executed by a computer processor, are used to implement an object connection method, and the object connection method comprises:
in response to a first trigger operation, acquiring a first action position and a second action position based on the first trigger operation, wherein the first action position is used to determine a first object to be connected;
determining a second object capable of establishing a connection to the first object, and creating a detection element corresponding to the second object, wherein the second object is in a detection region of the detection element, and an area of the detection region is greater than an area of the second object; and
in response to the second action position being in the detection region, connecting the first object to the second object in the detection region in response to a second trigger operation.
